(19) United States
(12) Patent Application Publication
(10) Pub. No.: US 2013/0200361 A1
(43) Pub. Date: Aug. 8, 2013

(54) THIN FILM TRANSISTOR HAVING AN ACTIVE LAYER CONSISTING OF MULTIPLE OXIDE SEMICONDUCTOR LAYERS

(71) Applicant: JIAN-SHIHN TSANG, Tu-Cheng (TW)

(72) Inventor: JIAN-SHIHN TSANG, Tu-Cheng (TW)

(73) Assignee: HON HAI PRECISION INDUSTRY CO., LTD., Tu-Cheng (TW)

(21) Appl. No.: 13/562,297

(22) Filed: Jul. 30, 2012

(30) Foreign Application Priority Data
Feb. 6, 2012 (TW) 101103706

(51) Int. Cl. H01L 29/786

(52) U.S. Cl. 257/43; 257/E29.296

(57) ABSTRACT

A thin film transistor includes a substrate, a gate electrode, and an active layer formed on the substrate. The active layer includes a channel region, a source region and a drain region located at two lateral portions of the channel region. The active layer includes a first oxide semiconductor material layer and a second oxide semiconductor material layer stacked to each other. Material of the first oxide semiconductor material layer is different from material of the second oxide semiconductor material layer. A gate insulating layer is formed between the channel region and the gate electrode. A source electrode electrically connects the source region. A drain electrode electrically connects the drain region.

### BACKGROUND

1. Technical Field

The disclosure generally relates to a thin film transistor (TFT), particularly to a TFT having an active layer consisting of a plurality of oxide semiconductor layers stacked on each other.

2. Description of Related Art

Nowadays, thin film transistors have been widely used in display devices to make the display devices become thinner and smaller. A typical thin film transistor includes a channel region, a source region and a drain region formed at two opposite ends of the channel region, respectively. A gate electrode is formed on the channel region. A source electrode and a drain electrode are formed on the source region and the drain region, respectively. The thin film transistor is turned on or turned off by controlling a voltage applied to the gate electrode.

Generally, the source region and the drain region each are made of an oxide semiconductor material such as InGaZnO. When the source electrode is applied to the source region, a contact resistance between the source electrode and the source region will have a high value due to the relatively low carrier concentration of the source region. Similarly, a contact resistance between the drain electrode and the drain region will have a high value due to a relatively low carrier concentration of the drain region. The high contact resistances will increase a driving voltage of the thin film transistor and reduce a response speed of the thin film transistor to a control signal.

What is needed, therefore, is a thin film transistor to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross-sectional view showing a thin film transistor in accordance with a first embodiment of the present disclosure.

FIG. 2 is a cross-sectional view showing a thin film transistor in accordance with a second embodiment of the present disclosure.

FIG. 3 is a cross-sectional view showing a thin film transistor in accordance with a third embodiment of the present disclosure.

### DETAILED DESCRIPTION

Embodiments of a thin film transistor will now be described in detail below and with reference to the drawings.

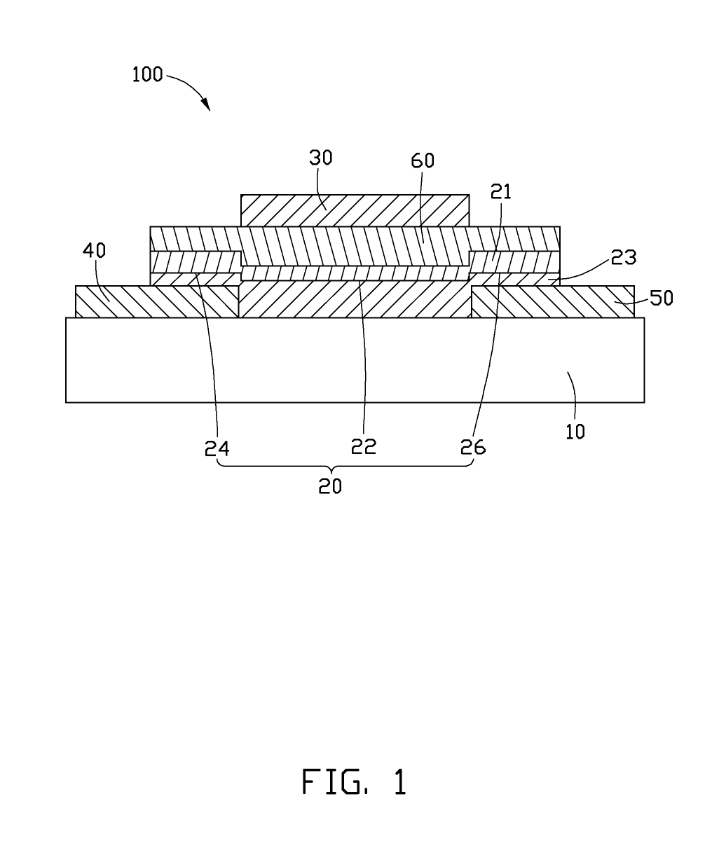

Referring to FIG. 1, a thin film transistor 100 in accordance with a first embodiment includes a substrate 10, an active layer 20 formed on the substrate 10, a gate electrode 30, a source electrode 40 and a drain electrode 50.

The substrate 10 is made of a material selected from a group consisting of glass, quartz, silicone, polycarbonate, polymethyl methacrylate and metal foil.

The active layer 20 is formed on an upper surface of the substrate 10. The active layer 20 includes a first oxide semiconductor material layer 21 and a second oxide semiconductor material layer 23. The first oxide semiconductor material layer 21 is made of an oxide semiconductor material selected from a group consisting of IGZO, ZnO, TiOx, GTO, GZO, AZO, IZO, ITO, and ATO. The second oxide semiconductor material layer 23 is made of an oxide semiconductor material selected from a group consisting of IGZO, ZnO, TiOx, GTO, GZO, AZO, IZO, ITO, and ATO. The material of the first oxide semiconductor material layer 21 is different from the material of the second oxide semiconductor material layer 23. In this embodiment, the second oxide semiconductor material layer 23 is formed on an upper surface of the substrate 10, and the first oxide semiconductor material layer 21 is formed on the second oxide semiconductor material layer 23. A bang gap of the second oxide semiconductor material layer 23 is less than a bang gap of the first oxide semiconductor material layer 21, whereby a carrier concentration of the first oxide semiconductor material layer 21 is less than a carrier concentration of the second oxide semiconductor material layer 23.

The active layer 20 includes a middle channel region 22, a source region 24 and a drain region 26 formed at two lateral portions of the channel region 22. The source region 24 and the drain region 26 are spaced from the substrate 10, respectively. Since the active layer 20 includes the first oxide semiconductor material layer 21 and the second oxide semiconductor material layer 23, the active layer 20 can resist the effect of a high temperature or a high humidity in outer environment. Similarly, since the first oxide semiconductor material layer 21 and the second oxide semiconductor material layer 23 are made of different material with different bang gaps, two dimensional conducting particles generated between the first oxide semiconductor material layer 21 and the second oxide semiconductor material layer 23 can increase electrical conductivity of the active layer 20.

The source electrode 40 and the drain electrode 50 are arranged at two lateral portions of the channel region 22 of the active layer 20. In this embodiment, the source electrode 40 is formed between the substrate 10 and the second oxide semiconductor material layer 23 of the active layer 20; the drain electrode 50 is formed between the substrate 10 and the second oxide semiconductor material layer 23. A width of each of the source electrode 40 and the drain electrode 50 is less than that of the channel region 22. The source electrode 40 electrically connects the source region 24 and an outer electrical source (not shown), and the drain electrode 50 electrically connects the drain region 26 and the outer electrical source to provide a voltage for driving the thin film transistor 100. The source electrode 40 and the drain electrode 50 both connect the second oxide semiconductor material layer 23 with high carrier concentration and low contact resistances, thereby increasing electrical conductivity of the active layer 20.

The gate electrode 30 is located above the channel region 22, and a gate insulating layer 60 is formed between the gate electrode 30 and the channel region 22. When the thin film transistor 100 is in use, voltages applied to the gate electrode 30 will control working states of the thin film transistor 100. For example, for an enhanced thin film transistor 100, when the gate electrode 30 is applied with a voltage greater than a threshold voltage of the thin film transistor 100, an electrically conductive channel will be formed in the channel region 22 to connect the source region 24 with the drain region 26, and the thin film transistor 100 is in an “on” state. When the gate electrode 30 is applied with a voltage of 0V, the electrical conductive channel will disappear in the channel region 22, and the thin film transistor 100 is in an “off” state. In this embodiment, the gate electrode 30 is made of a material selected from a group consisting of Au, Ag, Al, Cu, Cr, Ti, Mo and alloys thereof. The gate insulating layer 60 is made of a material selected from a group consisting of SiOx, SiNx, SiONx, Ta₂O₅, and HfO₂.

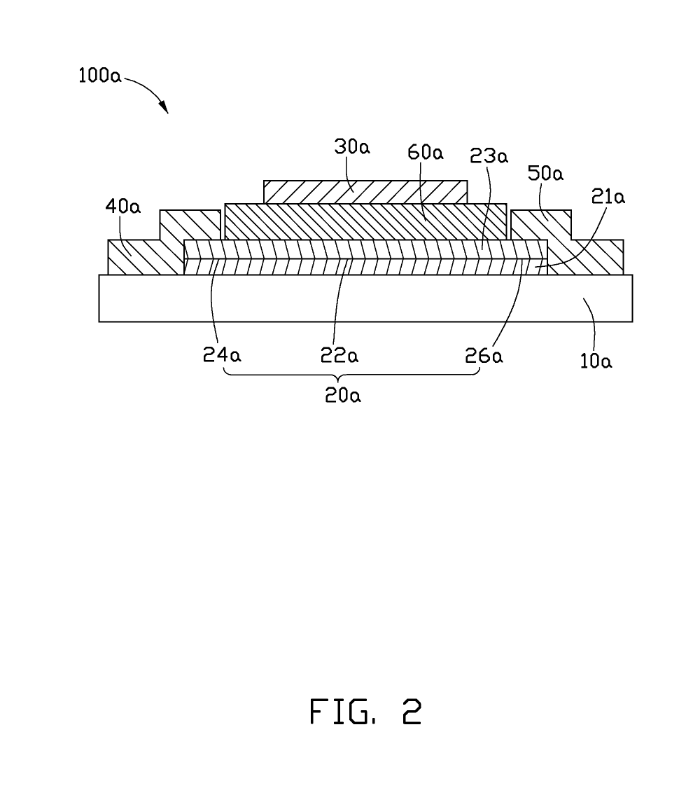

Referring to FIG. 2, a thin film transistor 100a in accordance with a second embodiment includes a substrate 10a, an active layer 20a, a gate electrode 30a, a gate insulating layer 60a, a source electrode 40a and a drain electrode 50a. The active layer 20a includes a first oxide semiconductor material layer 21a and a second oxide semiconductor material layer 23a. The active layer 20a includes a channel region 22a, a source region 24a and a drain 26a located at two lateral portions of the channel region 22a. Different from the first embodiment, the second oxide semiconductor material layer 23a is located on the first oxide semiconductor material layer 21a. The source region 24a and the drain region 26a are formed on an upper surface of the substrate 10a and at two lateral portions of the channel region 22a. An upper surface of the source region 24a and an upper surface of the drain region 26a are coplanar to an upper surface of the channel region 22a. The source electrode 40a is partly formed on the substrate 10a and partly formed on the source region 24a. The drain electrode 50a is partly formed on the substrate 10a and partly formed on the drain region 26a.

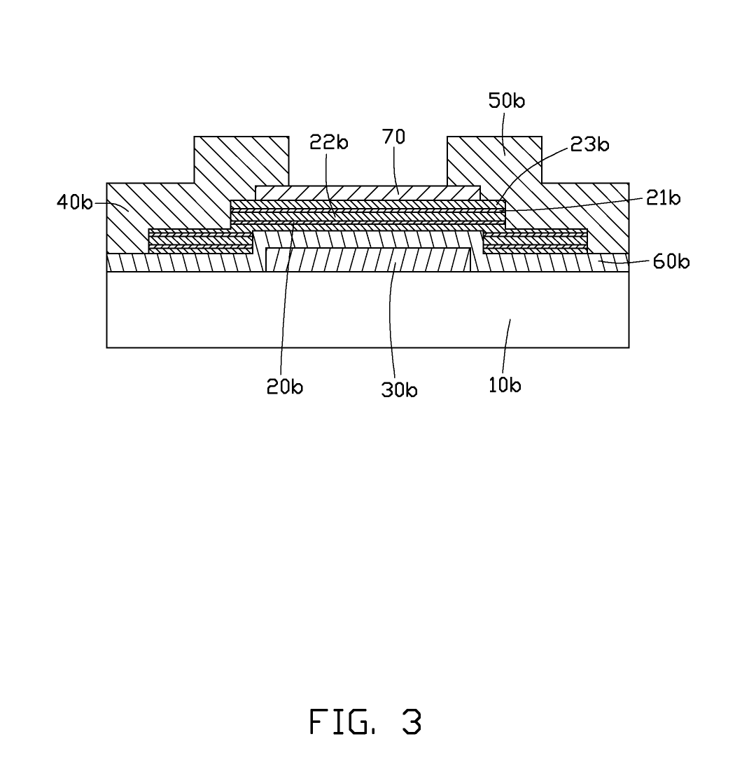

Referring to FIG. 3, a thin film transistor 100b in accordance with a third embodiment includes a substrate 10b, an active layer 20b, a gate electrode 30b, a gate insulating layer 60b, a source electrode 40b and a drain electrode 50b. Different from the thin film transistor 100a of FIG. 2, the gate electrode 30b is formed on the substrate 10b and under the active layer 20b. The gate insulating layer 60b is formed between the active layer 20b and the gate electrode 30b. The active layer 20b includes a plurality of first oxide semiconductor material layers 21b and second oxide semiconductor material layers 23b alternately stacked together. The thin film transistor 100b further includes an etching block layer 70 located on a center of the upper surface of a channel region 22b of the active layer 20b. The source electrode 40b and the drain electrode 50b cover parts of the etching block layer 70. The etching block layer 70 is made of an electrically insulating material, which is selected from a group consisting of SiOₓ, SiNₓ, and SiONₓ, which can prevent the channel region 22b from being affecting by metallic atoms from the source electrode 40b and the drain electrode 50b.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A thin film transistor comprising:
a substrate;
an active layer formed on the substrate, the active layer comprising a channel region, a source region and a drain region located at two lateral portions of the channel region, the active layer comprising a first oxide semiconductor material layer and a second oxide semiconductor material layer stacked to each other, material of the first oxide semiconductor material layer being different from material of the second oxide semiconductor material layer;
a gate electrode;
a gate insulating layer formed between the channel region and the gate electrode;
a source electrode electrically connecting the source region; and
a drain electrode electrically connecting the drain region.

2. The thin film transistor of claim 1, wherein the gate insulating layer is formed on the channel region, and the gate electrode is formed on the gate insulating layer.

3. The thin film transistor of claim 1, wherein a material of the active layer is selected from a group consisting of IGZO, IZO, AZO, GZO, ITO, GTO, ATO, TiOx and ZnO.

4. The thin film transistor of claim 1, wherein a bang gap of the second oxide semiconductor material layer is less than a bang gap of the first oxide semiconductor material layer.

5. The thin film transistor of claim 4, wherein the source electrode and the drain electrode are electrically connected to the second oxide semiconductor material layer.

6. The thin film transistor of claim 5, wherein the source electrode is located between the source region and the substrate, the drain electrode being located between the drain region and the substrate.

7. The thin film transistor of claim 1, wherein a carrier concentration of the first oxide semiconductor material layer is less than a carrier concentration of the second oxide semiconductor material layer.

8. The thin film transistor of claim 1, wherein the gate electrode is formed on the substrate and under the active layer.

9. The thin film transistor of claim 8, wherein an etching block layer is formed on upper surface of a channel region of the active layer, the source electrode and the drain electrode covering parts of the etching block layer.

10. A thin film transistor comprising:
a substrate;
an active layer formed on the substrate, the active layer comprising a channel region, a source region and a drain region located at two lateral portions of the channel region, the active layer comprising a plurality of first oxide semiconductor material layers and a plurality of second oxide semiconductor material layers alternately stacked together, material of the first oxide semiconductor material layers being different from material of the second oxide semiconductor material layers;
a gate electrode;
a gate insulating layer formed between the channel region and the gate electrode;
a source electrode electrically connecting the source region; and
a drain electrode electrically connecting the drain region.

11. The thin film transistor of claim 10, wherein a material of the active layer is selected from a group consisting of IGZO, IZO, AZO, GZO, ITO, GTO, ATO, TiOx and ZnO.

12. The thin film transistor of claim 10, wherein a bang gap of each of the second oxide semiconductor material layers is less than a bang gap of each of the first oxide semiconductor material layers.

13. The thin film transistor of claim 10, wherein a carrier concentration of each of the first oxide semiconductor material layers is less than a carrier concentration of each of the second oxide semiconductor material layers.

14. The thin film transistor of claim 10, wherein the gate electrode is formed on the substrate and under the active layer.

15. The thin film transistor of claim 14, wherein an etching block layer is formed on the upper surface of a channel region of the active layer, the source electrode and the drain electrode covering parts of the etching block layer.
